(19) United States
(12) Patent Application Publication
(10) Pub. No.: US 2008/0123315 A1
(43) Pub. Date: May 29, 2008

(54) DISPLAY FILTER, METHOD OF MANUFACTURING DISPLAY FILTER, AND PLASMA DISPLAY APPARATUS USING THE DISPLAY FILTER

(75) Inventors: Dongoh SHIN, Seoul (KR); Kyungku KIM, Seoul (KR); Namseok KANG, Seoul (KR)

Correspondence Address: FISH & RICHARDSON P.C., P.O. BOX 1022, MINNEAPOLIS, MN, 55440-1022, US

(73) Assignee: LG Electronics Inc., Seoul (KR)

(21) Appl. No.: 11/945,670

(22) Filed: Nov. 27, 2007

(30) Foreign Application Priority Data
Nov. 28, 2006 (KR) 10-2006-0118656
Nov. 28, 2006 (KR) 10-2006-0118658
Nov. 28, 2006 (KR) 10-2006-0118659

(51) Int. Cl. H05K 9/00; H01J 17/49; B29C 65/00

(52) U.S. Cl. 361/816; 156/196; 174/381

(57) ABSTRACT

A plasma display apparatus comprises plasma display panel and a display filter. The plasma display panel that receives a driving voltage through a scan electrode, a sustain electrode, and data electrodes to emit light. The display filter provided over the plasma display panel. The display filter comprises a base layer and an electromagnetic shielding layer positioned over the base layer. The electromagnetic shielding layer comprises an effective region in which a first mesh pattern is formed and a non-effective region in which a second mesh pattern having a larger width than the width of the first mesh pattern is formed.

This non-provisional application claims priority under 35 U.S.C. §119(a) on Patent Application Nos. 10-2006-0118656, 10-2006-0118658, and 10-2006-0118659 filed in Republic of Korea on Nov. 28, 2006 the entire contents of which are hereby incorporated by reference.

### BACKGROUND

1. Field

This document relates to a display filter, a method of manufacturing a display filter, and a plasma display apparatus using the display filter.

2. Related Art

In general, a plasma display apparatus comprises a plasma display panel (PDP) and a display filter provided on the top surface of the PDP.

The PDP comprises a top surface panel and a bottom surface panel to form a unit discharge cell by barrier ribs of the bottom surface panel. A main discharge gas such as neon (Ne), helium (He), and an air mixture of Ne+He and an inert gas comprising a small amount of xenon are filled in each cell.

When a high frequency voltage is applied to the discharge cell, discharge occurs so that the inert gas generates vacuum ultraviolet (UV) rays. The UV rays emit light from a phosphor formed between the barrier ribs.

A display filter having a predetermined function is provided on the top surface of the PDP. The display filter comprises an electromagnetic shielding layer having a predetermined pattern.

### SUMMARY

An aspect of this document is to provide a method of manufacturing a display filter, comprising applying an electromagnetic shielding paste to a printing plate including a first pattern formed in the center of the printing plate and a second pattern formed in a periphery of the center, the second pattern having a width larger than a width of the first pattern, and separating the electromagnetic shielding paste from the printing plate and attaching the separated electromagnetic shielding paste to a base layer.

A display filter according to the present invention comprises a base layer and an electromagnetic shielding layer positioned over the base layer and comprising a first region in which a first mesh pattern is formed and a second region in which a second mesh pattern, which has a larger width than the width of the first mesh pattern, is formed.

A plasma display apparatus according to the present invention comprises a plasma display panel that receives a driving voltage through a scan electrode, a sustain electrode, and data electrodes to emit light and a display filter provided over the plasma display panel, the display filter comprising a base layer and an electromagnetic shielding layer positioned over the base layer, the electromagnetic shielding layer comprising an effective region in which a first mesh pattern is formed and a non-effective region in which a second mesh pattern having a larger width than the width of the first mesh pattern is formed.

### BRIEF DESCRIPTION OF THE DRAWINGS

The implementation of this document will be described in detail with reference to the following drawings in which like numerals refer to like elements.

FIGS. 1A to 1C illustrate a plasma display apparatus according to an embodiment of the present invention;

FIG. 2 illustrates an example of a plasma display panel (PDP) according to the present invention;

FIGS. 3A to 3C illustrate a method of manufacturing a display filter according to an embodiment of the present invention;

FIGS. 4A to 4C illustrate the structure of a printing plate; and

FIGS. 5A to 5C illustrate the supporting part of the printing plate.

### DETAILED DESCRIPTION

Embodiments will be described in a more detailed manner with reference to the drawings.

A method of manufacturing a display filter according to the present invention comprises applying an electromagnetic shielding paste to a printing plate including a first pattern formed in the center of the printing plate and a second pattern formed in a periphery of the center, the second pattern having a width larger than a width of the first pattern, and separating the electromagnetic shielding paste from the printing plate and attaching the separated electromagnetic shielding paste to a base layer.

The printing plate may comprise a first recessed part having the first pattern and a second recessed part having the second pattern, and a depth of the second recessed part may be smaller than a depth of the first recessed part.

A height of the electromagnetic shielding paste corresponding to the first pattern attached to the base layer may be substantially equal to a height of the electromagnetic shielding paste corresponding to the second pattern attached to the base layer.

A width of the first recessed part may be no more than 100 μm and a depth of the first recessed part is larger than 25 μm and less than 35 μm, and a second width of the printing plate may be larger than 100 μm and a second depth of the printing plate is no less than 15 μm and no more than 25 μm.

At least one supporting part may be formed in the second recessed part.

The printing plate may comprise a first recessed part having the first pattern and a second recessed part having the second pattern, a depth of the first recessed part may be equal to a depth of the second recessed part, and at least one supporting part may be formed in the second recessed part.

Adhesive strength between the electromagnetic shielding paste and the printing plate may be smaller than adhesive strength between the electromagnetic shielding paste and the base layer.

The electromagnetic shielding paste may be applied by a blade.

A display filter according to the present invention comprises a base layer and an electromagnetic shielding layer positioned over the base layer and comprising a first region in which a first mesh pattern is formed and a second region in which a second mesh pattern, which has a larger width than the width of the first mesh pattern, is formed.

The second region may surround the first region.

A width of the second pattern of the electromagnetic shielding layer can be no less than 20 μm and no more than 400 μm.

The width of the second mesh pattern of the electromagnetic shielding layer may be no less than 100 μm and no more than 200 μm.

A width of the first mesh pattern of the electromagnetic shielding layer may be no less than 10 μm and no more than 30 μm.

A plasma display apparatus according to the present invention comprises a plasma display panel that receives a driving voltage through a scan electrode, a sustain electrode, and data electrodes to emit light and a display filter provided over the plasma display panel, the display filter comprising a base layer and an electromagnetic shielding layer positioned over the base layer, the electromagnetic shielding layer comprising an effective region in which a first mesh pattern is formed and a non-effective region in which a second mesh pattern having a larger width than the width of the first mesh pattern is formed.

The non-effective region may surround the effective region.

A width of the second mesh pattern of the electromagnetic shielding layer may be no less than 20 μm and no more than 400 μm.

The width of the second mesh pattern of the electromagnetic shielding layer may be no less than 100 μm and no more than 200 μm.

A width of the first mesh pattern of the electromagnetic shielding layer may be no less than 10 μm and no more than 30 μm.

Hereinafter, an implementation of this document will be described in detail with reference to the attached drawings.

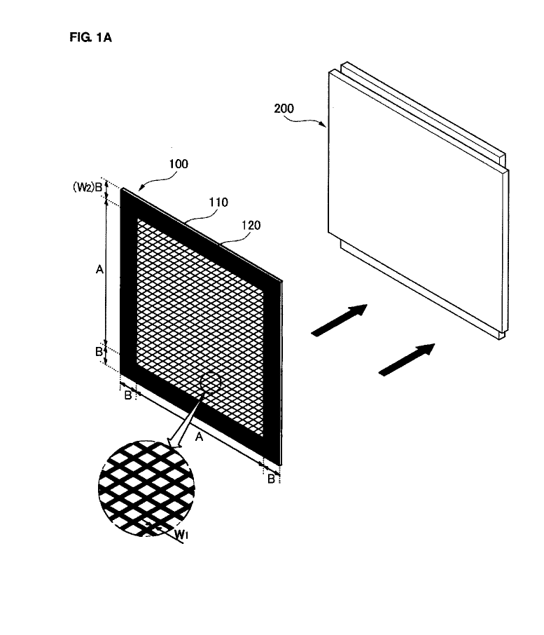

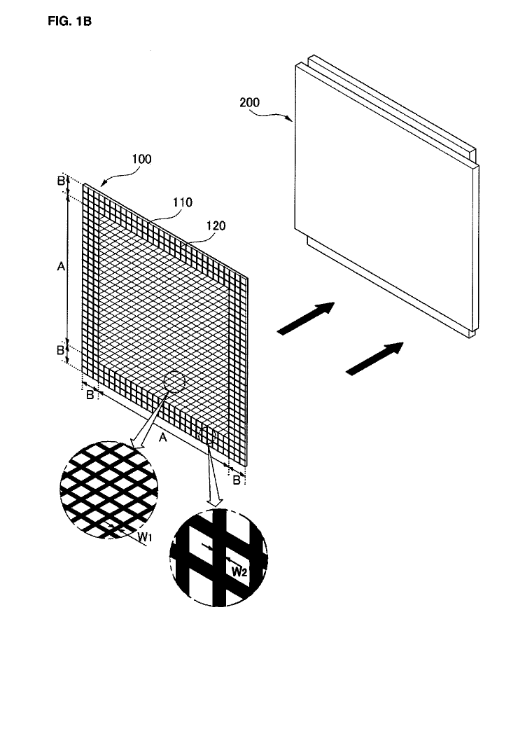

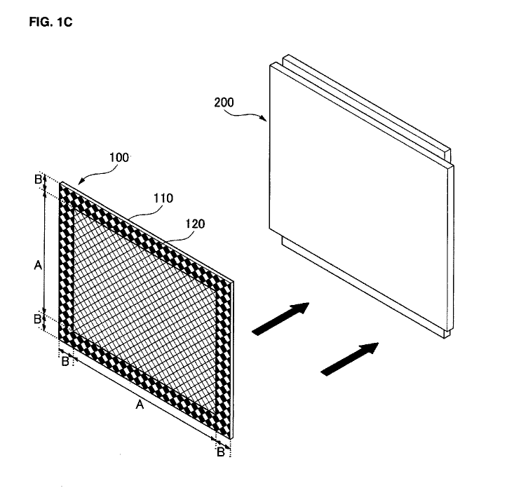

FIGS. 1A to 1C illustrate a plasma display apparatus according to an embodiment of the present invention.

As illustrated in FIGS. 1A to 1C, the plasma display apparatus according to an embodiment of the present invention comprises a plasma display panel (PDP) 200 and a display filter 100.

The PDP 200 comprises a scan electrode, a sustain electrode, and data electrodes so that driving units (not shown) supply a driving voltage to electrodes to generate discharge.

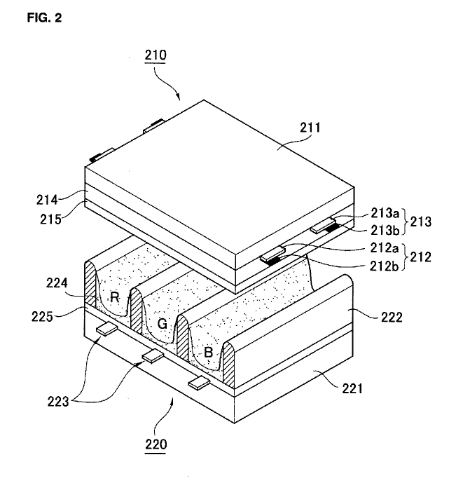

FIG. 2 illustrates an example of a PDP according to the present invention. As illustrated in FIG. 2, in the PDP, a scan electrode 212Y and a sustain electrode 213Z are formed over a top surface substrate 211 and a plurality of data electrodes 223 that intersect the scan electrode 212Y and the sustain electrode 213Z are formed over a bottom surface substrate 221.

The scan electrode 212 and the sustain electrode 213 can comprise transparent electrodes 212a and 213a formed of indium tin oxide (ITO) and bus electrodes 212b and 213b formed of metal. In addition, the scan electrodes 212 and 213 can comprise only the bus electrodes 212b and 213b.

An upper dielectric layer 214 covers the scan electrode 212 and the sustain electrode 213 to insulate the scan electrode 212 and the sustain electrode 213 from each other. A protective layer 215 is formed over the upper dielectric layer 214 and can be formed of magnesium oxide (MgO).

A lower dielectric layer 225 covers the data electrodes 223 to insulate the data electrodes 223 from each other. Barrier ribs 222 are formed over the lower dielectric layer 225 to partition off discharge cells.

Phosphors 224 are applied between the barrier ribs 222 to be excited by discharge and to emit light.

As illustrated in FIG. 1A, the display filter 100 is provided over the top surface of the PDP 200. The display filter 100 comprises a base layer 110 and an electromagnetic shielding layer 120. The electromagnetic shielding layer 120 is positioned over the base layer 110. The electromagnetic shielding layer 120 comprises a first region A in which a first mesh pattern is formed and a second region B that surrounds the first region A and that has a width w2 larger than the width w1 of the first mesh pattern.

In addition, as illustrated in FIG. 1B, the electromagnetic shielding layer 120 comprises the first region A in which the first mesh pattern is formed and the second region B that surrounds the first region A and in which a second mesh pattern having a larger width w2 than the width w1 of the first mesh pattern is formed.

As illustrated in FIG. 1C, the electromagnetic shielding layer 120 comprises the first region A in which the first mesh pattern is formed and the second region B that surrounds the first region A and in which a second mesh pattern having a larger width w2 than the width w1 of the first mesh pattern is formed. The shape of the second mesh pattern of FIG. 1C can be different from the shape of the second mesh pattern of FIG. 1B.

In the electromagnetic shielding layer 120 illustrated in FIGS. 1A to 1C, the first region A corresponds to the center of the electromagnetic shielding layer 120 and the second region B corresponds to the periphery of the center of the electromagnetic shielding layer 120. The electromagnetic shielding layer 120 formed in the second region B of FIGS. 1A to 1C functions as a ground.

In the electromagnetic shielding layer 120 illustrated in FIGS. 1A to 1C, the first region A corresponds to the effective region of the PDP 200 that emits light and the second region B corresponds to the non-effective region of the PDP 200 that does not emit light.

In the first region A corresponding to the effective region of the PDP, the width w1 of the first mesh pattern is smaller than the width w2 of the second region of FIG. 1A or the second mesh pattern of FIGS. 1B and 1C to increase the transmittance of the light emitted from the PDP. In addition, the width w2 of the second region of FIG. 1A or the second mesh pattern of FIGS. 1B and 1C is larger than the width w1 of the first mesh pattern to reduce the resistance of the electromagnetic shielding layer caused by the second mesh pattern and to increase electromagnetic shielding effect.

In order to increase the transmittance of light and the electromagnetic shielding effect, the width w1 of the first mesh pattern can be no less than 10 μm and no more than 30 and the width w2 of the second mesh pattern can be no less than 20 μm and no more than 400μ. In particular, when the width w2 of the second mesh pattern is no less than 100 μm and no more than 200μ, it is possible to increase the electromagnetic shielding effect and to optimize the use of electromagnetic shielding material.

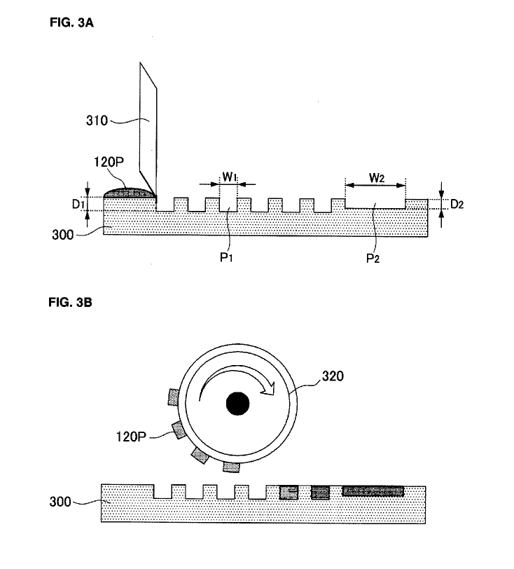

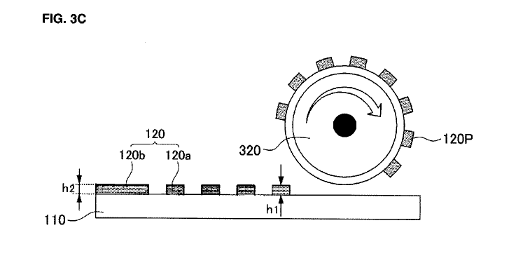

FIGS. 3A to 3C illustrate a method of manufacturing a display filter according to an embodiment of the present invention. The display filter according to an embodiment of the present invention can be formed by a direct patterning method, for example, an offset method.

As illustrated in FIG. 3A, a printing plate 300 comprising a first pattern formed in the center thereof and a second pattern formed in the periphery of the center and having a larger width w2 than the width w1 of the first pattern is coated with an electromagnetic shielding paste 120P. The electromagnetic shielding paste 120P is a conductive paste. The first pattern corresponds to the first mesh pattern of FIGS. 1A to 1C. The second pattern may be formed in the second region B, and may correspond to the second mesh pattern of FIGS. 1B and 1C.

That is, the printing plate 300 comprises a first recessed part P1 and a second recessed part P2. The first recessed part P1 is formed in accordance with the first pattern and the second recessed part P2 is formed in accordance with the second pattern. The first pattern corresponds to the first mesh pattern illustrated in FIGS. 1A and 1B and the second pattern corresponds to the second region B of FIG. 1A or the second mesh pattern of FIG. 1B. Therefore, the width w1 of the first recessed part P1 is substantially equal to the width w1 of the first mesh pattern of FIGS. 1A and 1B and the width w2 of the second recessed part P2 is substantially equal to the width w2 of the second region B of FIG. 1A or the width w2 of the second mesh pattern of FIG. 1B. As described above, since the second region B of FIG. 1A or the width w2 of the second mesh pattern of FIG. 1B is larger than the width w1 of the first mesh pattern, the width w2 of the second recessed part P2 is larger than the width w1 of the first recessed part P1. over the other hand, the depth D2 of the second recessed part P2 can be smaller than the depth D1 of the first recessed part P1.

The electromagnetic shielding paste 120P is applied to the first recessed part P1 and the second recessed part P2 of the printing plate 300 by a blade 310.

As illustrated in FIG. 3B, the electromagnetic shielding paste 120P applied to the first recessed part P1 and the second recessed part P2 is separated from the printing plate 300 by a blanket 320. That is, the blanket 320 rotates so that the surface of the blanket 320 contacts the surface of the electromagnetic shielding paste 120P applied to the first recessed part P1 and the second recessed part P2 and that the electromagnetic shielding paste 120P is separated from the printing plate 300.

As illustrated in FIG. 3C, the electromagnetic shielding paste 120P separated by the blanket 320 is attached to the base layer 110 of FIGS. 1A and 1B to form the electromagnetic shielding layer 120. The base layer 110 can be a glass substrate. An electromagnetic shielding layer 120b corresponds to the second region B of FIG. 1A or the second mesh pattern of FIG. 1B and an electromagnetic shielding layer 120a corresponds to the first mesh pattern of FIGS. 1A and 1B.

The height h1 of the electromagnetic shielding paste corresponding to the first pattern attached to the base layer 110 is substantially equal to the height h2 of the electromagnetic shielding paste corresponding to the second pattern.

At this time, the depth D1 of the first recessed part P1 is different from the depth D2 of the second recessed part P2. However, the height h1 of the electromagnetic shielding layer 120a can be substantially equal to the height h2 of the electromagnetic shielding layer 120b.

As illustrated in FIG. 3B, in order to separate the electromagnetic shielding paste 120P from the printing plate 300 by the blanket 320, adhesive strength between the blanket 320 and the electromagnetic shielding paste 120P is larger than adhesive strength between the printing plate 300 and the electromagnetic shielding paste 120P. In addition, as illustrated in FIG. 3C, in order to apply the electromagnetic shielding paste 120P from the blanket 320 to the base layer 110, adhesive strength between the base layer 110 and the electromagnetic shielding layer 120P is larger than adhesive strength between the blanket 320 and the electromagnetic shielding paste 120P. Therefore, adhesive strength between the electromagnetic shielding paste 120P and the printing plate 300 is smaller than adhesive strength between the electromagnetic shielding paste 120P and the base layer 110.

As illustrated in FIGS. 3A to 3C, the display filter according to the present invention can be easily and simply manufactured by the direct patterning method such as the offset method rather than a photolithography process.

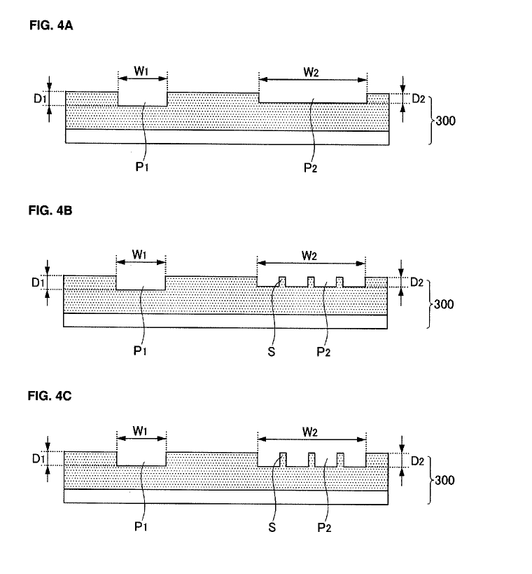

As illustrated in FIG. 4A, the printing plate 300 for forming the electromagnetic shielding layer comprises the first recessed part P1 and the second recessed part P2. The width w2 of the second recessed part P2 can be larger than the width w1 of the first recessed part P1 and the depth D2 of the second recessed part P2 can be smaller than the width D2 of the second recessed part P2.

As illustrated in FIG. 3B, in the process of separating the electromagnetic shielding layer 120 applied to the printing plate 300, since the width w1 of the first recessed part P1 is small, when the depth of the first recessed part P1 is equal to the depth D2 of the second recessed part P2, the amount of the electromagnetic shielding paste 120P applied to the first recessed part P1 is smaller than the amount of the electromagnetic shielding paste 120P applied to the second recessed part P2. When the amount of the electromagnetic shielding paste 120P applied to the first recessed part P1 is smaller than the amount of the electromagnetic shielding paste 120P applied to the second recessed part P2, the height of the electromagnetic shielding layer 120a formed by the first recessed part P1 can be smaller than the height of the electromagnetic shielding layer 120b formed by the second recessed part P2. Therefore, the electromagnetic shielding layer can be non-uniformly formed.

Therefore, in the embodiment of the present invention, the depth D1 of the first recessed part P1 is larger than the depth D2 of the second recessed part P2. When the width w1 of the first recessed part P1 is no more than 100 μm, the depth D1 of the first recessed part P1 can be larger than 25 μm and less than 35 μm. In addition, when the width w2 of the second recessed part P2 is larger than 100 μm, the depth D2 of the second recessed part P2 can be no less than 15 μm and no more than 25 μm. Therefore, the heights h1 and h2 of the electromagnetic shielding layers 120a and 120b illustrated in FIG. 3C can be substantially equal to each other. As a result, the electromagnetic shielding layer can be uniformly formed.

As illustrated in FIG. 4B, at least one supporting units S can be formed in the second recessed part P2 of the printing plate 300. That is, the supporting parts S are formed in the second recessed part P2 having a large width so that, when the electromagnetic shielding paste 120P is applied to the printing plate 300 by the blade 310, the blade 310 is not inserted into the second recessed part P2 to prevent the electromagnetic shielding paste 120P from being damaged or scratched.

As illustrated in FIG. 4C, at least one supporting units S can be formed in the second recessed part P2 of the printing plate 300. At this time, the depth D1 of the first recessed part P1 can be substantially equal to the depth D2 of the second recessed part P2. In the printing plate 300 of FIG. 4C, the heights of the electromagnetic shielding layers can vary, however, it is possible to prevent the electromagnetic shielding paste 120P from being damaged or scratched.

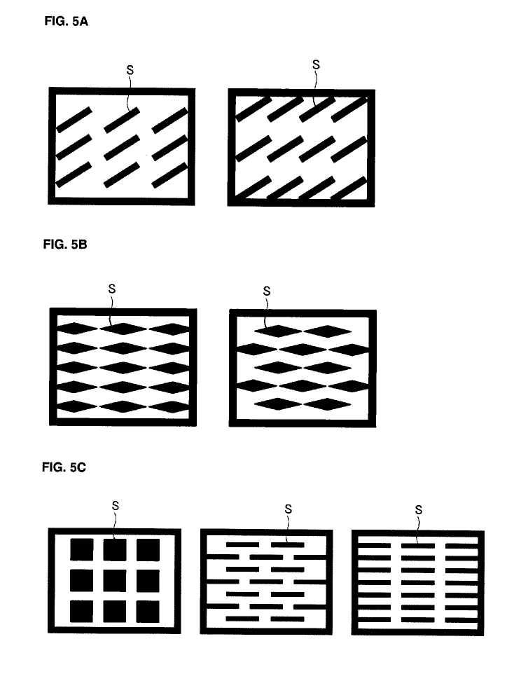

As illustrated in FIGS. 5A to 5C, the shapes of the supporting parts S formed in the second recessed part P2 can vary.

In the embodiment of the present invention, the display filter is provided in the plasma display apparatus. However, the display filter can be provided in a flat panel display (FPD) such as a liquid crystal display (LCD) or an organic light emitting display.

The foregoing embodiments and advantages are merely exemplary and are not to be construed as limiting the present invention. The present teaching can be readily applied to other types of apparatuses. The description of the foregoing embodiments is intended to be illustrative, and not to limit the scope of the claims. Many alternatives, modifications, and variations will be apparent to those skilled in the art. In the claims, means-plus-function clauses are intended to cover the structures described herein as performing the recited function and not only structural equivalents but also equivalent structures. Moreover, unless the term “means” is explicitly recited in a limitation of the claims, such limitation is not intended to be interpreted under 35 USC 112(6).

What is claimed is:

1. A method of manufacturing a display filter, comprising:
applying an electromagnetic shielding paste to a printing plate including a first pattern formed in the center of the printing plate and a second pattern formed in a periphery of the center, the second pattern having a width larger than a width of the first pattern; and
separating the electromagnetic shielding paste from the printing plate and attaching the separated electromagnetic shielding paste to a base layer.

2. The method of claim 1,
wherein the printing plate comprises a first recessed part having the first pattern and a second recessed part having the second pattern, and
wherein a depth of the second recessed part is smaller than a depth of the first recessed part.

3. The method of claim 1, wherein a height of the electromagnetic shielding paste corresponding to the first pattern attached to the base layer is substantially equal to a height of the electromagnetic shielding paste corresponding to the second pattern attached to the base layer.

4. The method of claim 2,
wherein a width of the first recessed part is no more than 100 μm and a depth of the first recessed part is larger than 25 μm and less than 35 μm, and
wherein a second width of the printing plate is larger than 100 μm and a second depth of the printing plate is no less than 15 μm and no more than 25 μm.

5. The method of claim 2, wherein at least one supporting part is formed in the second recessed part.

6. The method of claim 1,
wherein the printing plate comprises a first recessed part having the first pattern and a second recessed part having the second pattern,
wherein a depth of the first recessed part is equal to a depth of the second recessed part, and
wherein at least one supporting part is formed in the second recessed part.

7. The method of claim 1, wherein adhesive strength between the electromagnetic shielding paste and the printing plate is smaller than adhesive strength between the electromagnetic shielding paste and the base layer.

8. The method of claim 1, wherein the electromagnetic shielding paste is applied by a blade.

9. A display filter, comprising:
a base layer; and
an electromagnetic shielding layer positioned over the base layer and comprising a first region in which a first mesh pattern is formed and a second region in which a second mesh pattern, which has a larger width than the width of the first mesh pattern, is formed.

10. The display filter of claim 9, wherein the second region surrounds the first region.

11. The display filter of claim 9, wherein a width of the second mesh pattern of the electromagnetic shielding layer is no less than 20 μm and no more than 400 μm.

12. The display filter of claim 9, wherein the width of the second mesh pattern of the electromagnetic shielding layer is no less than 100 μm and no more than 200 μm.

13. The display filter of claim 9, wherein a width of the first mesh pattern of the electromagnetic shielding layer is no less than 10 μm and no more than 30 μm.

14. A plasma display apparatus, comprising:
a plasma display panel that receives a driving voltage through a scan electrode, a sustain electrode, and data electrodes to emit light; and
a display filter provided over the plasma display panel, the display filter comprising a base layer and an electromagnetic shielding layer positioned over the base layer, the electromagnetic shielding layer comprising an effective region in which a first mesh pattern is formed and a non-effective region in which a second mesh pattern having a larger width than the width of the first mesh pattern is formed.

15. The plasma display apparatus of claim 14, wherein the non-effective region surrounds the effective region.

16. The plasma display apparatus of claim 14, wherein a width of the second mesh pattern of the electromagnetic shielding layer is no less than 20 μm and no more than 400 μm.

17. The plasma display apparatus of claim 14, wherein the width of the second mesh pattern of the electromagnetic shielding layer is no less than 100 μm and no more than 200 μm.

18. The plasma display apparatus of claim 14, wherein a width of the first mesh pattern of the electromagnetic shielding layer is no less than 10 μm and no more than 30 μm.
